(19) United States
(12) Patent Application Publication
(10) Pub. No.: US 2013/0181720 A1
(43) Pub. Date: Jul. 18, 2013

(54) BATTERY SENSOR

(71) Applicant: Robert Bosch GmbH, Stuttgart (DE)

(72) Inventor: Marcus Bremmer, Benningen Am Neckar (DE)

(73) Assignee: ROBERT BOSCH GMBH, Stuttgart (DE)

(21) Appl. No.: 13/740,424

(22) Filed: Jan. 14, 2013

(30) Foreign Application Priority Data
Jan. 13, 2012 (DE) 10 2012 200 508.0

(51) Int. Cl. G01R 31/36

(52) U.S. Cl. CPC G01R 31/3644
USPC 324/426

(57) ABSTRACT

A battery sensor for determining at least one operational parameter of a battery, wherein the battery sensor comprises at least one transistor having controllable resistance, which is designed to determine the at least one operational parameter.

### BACKGROUND OF THE INVENTION

The invention relates to a battery sensor and a method for determining at least one battery operational parameter of a battery.

### TECHNICAL FIELD

Today's precision battery sensors use passive resistance materials for measuring current, which frequently comprise Manganin an alloy of copper, manganese, and nickel for achieving a desired temperature stability. A drop in voltage of a battery is thereby detected via a resistor consisting of Manganin, which is configured as a shunt and comprises a component of a battery sensor. The flowing current is ascertained from said drop in voltage. The shunt is thereby generally designed for 100 μΩ. This resistance value, which was determined during the development of the battery sensor, cannot be changed over the service life of said battery sensor. For that reason, resistance tolerances can restrict the maximum measurement range of the battery sensor.

The requirements placed on detecting a state of an energy storage unit designed as a battery are continuously increasing. In order to measure the state of a battery, methods for impedance spectroscopy are used, with which the reaction of the battery to excitations of different frequencies is analyzed.

The European Patent Office patent publication EP 1 920 264 B1 discloses a battery sensor unit having a fastening apparatus for fastening the battery sensor unit to a contact of a motor vehicle battery and having a measurement section for detecting the state of the motor vehicle battery. In so doing, the cylindrical measurement section is in the form of a measurement shunt, wherein said measurement section and the fastening apparatus are combined to form an integral structural unit.

### SUMMARY OF THE INVENTION

The resistance function of the battery sensor is not implemented via a passive electrical resistor but via at least one electronically controllable transistor, typically a power transistor. As one embodiment, the battery sensor can have a transistor comprising a controllable or controlled resistor as the measuring resistor. It is possible to suitably adjust the value of a resistance of the at least one transistor via, e.g., an evaluation, control and regulating device that is connected to a gate and source of the transistor. The at least one transistor is disposed along a measurement section of a main current circuit of the battery sensor. A value of the resistance of the at least one transistor can be controlled and therefore be adjusted to regulate a measurement range of the battery sensor. For this purpose, the value of the resistance of the at least one transistor is automatically adapted to a value and/or a level of an operational parameter of the battery to be determined.

The cost-driving function for present-day battery sensors is current measurement. A shunt required for this purpose involves a relatively large proportion of the costs. The costs for the battery sensor can be reduced with the present invention by replacing the shunt with the at least one transistor, e.g., with a plurality of transistors connected in parallel or in series. As a result of the advantageous analog measuring technology, the battery sensor can be supplemented by additional, value-increasing functions without incurring additional costs.

The shunt is replaced by at least one transistor which, e.g., is designed as a power transistor that is typically embodied as a normal conducting power MOSFET in order to ensure current flow in the deactivated state and thereby to facilitate the intrinsic safety of the battery sensor. Alternative transistor technologies are also conceivable for implementing the battery sensor.

Depending on the measuring requirements of an evaluation unit used as an additional component of the battery sensor, the resistance of the at least one transistor can be regulated by setting a measurement range of the transistor for measuring a voltage or a current. In so doing, the resistance of the at least one transistor is adjusted, as an operational parameter, as a function of the level of a current to be measured or a voltage to be measured.

At high current values, a measurement can also be carried out with lower resolution. The resistance of the at least one transistor can in this case be reduced by the evaluation, control and regulating device in order to keep the power loss low.

At low current values, a higher degree of accuracy is required. When actively controlling components, the resistance of the at least one transistor can be increased, and the battery sensor can ideally make use of a measurement range of an analog/digital converter.

The resolution of present-day analog/digital converters in battery sensors is typically 16 bits. Using the present invention, the resolution of the analog/digital converter can be reduced because the resistance of the at least one transistor is dynamically executed. The complicated analog metrology for measuring very low currents of the order of 1 mA can be cost effectively performed. When the resistance is set correspondingly large, even currents, which are smaller than 1 mA, can be analyzed. Said analog metrology can be used for error diagnosis during motor vehicle production.

The evaluation unit, which is designed by way of example as an ASIC (Application Specific Integrated Circuit), is capable of accurately measuring the voltage in the range of a few μV. It is therefore possible to cover a measurement range of a current, which extends from approximately lmA up to approximately 1 kA over a range of six powers of ten, with the at least one transistor.

The use of transistors, which can be embodied as power transistors in the power path of the battery sensor, facilitates to some extent an active excitation when charging or if applicable when discharging the battery. In the event of the battery sensor being used, e.g., for a battery of a motor vehicle, an algorithm being used is therefore more independent of external loads in the motor vehicle because, as at least one operational parameter of the battery, the battery sensor can itself exert influence on the current to be measured or the voltage to be measured by automatically regulating the resistance provided for the measuring procedure.

The state of the battery can typically be detected (battery state detection) using the battery sensor. For example, a state of charge can thereby be determined as the battery state (state of health). The state of the battery is determined on the basis of at least one battery parameter measured by the battery sensor, e.g. the voltage U_{Batt} present at the battery, the current I_{Batt} flowing through the battery and/or the temperature of the battery. The battery, for which the battery sensor is provided for determining the state via the at least one battery parameter, can be discharged as well as charged and thus can also be designed and/or designated in embodiment as a rechargeable battery. The at least one operational parameter, typically the current I_{Batt} of the battery and therefore of a battery embodied as a rechargeable battery, is detected via the at least one variable resistor in the main current circuit of the battery sensor.

The at least one transistor having a variable and/or controllable resistor in the main current circuit thus facilitates further a limitation of the charging current for the battery in a measurement section of the battery sensor, whereby a charging strategy of the battery is optimized and the service life thereof can be extended. This serves as a protective function.

In addition, a power distribution can be optimized in an on-board electrical system of a motor vehicle, which comprises the battery. The power supplied by a generator can be selectively controlled by means of an increased resistance in a feed cable to the battery. For this purpose, the value of the resistance of the at least one transistor of the battery sensor is set in this embodiment. When the state of charge of the battery is low, the at least one transistor of the battery sensor can, e.g., be switched to high resistance and thus the energy supplied by the generator can if necessary be selectively provided to safety-critical loads, e.g. an electrically assisted steering. It is therefore possible to control the power supply within the on-board electrical system with the battery sensor according to the invention.

The resistance of the at least one transistor can be set in a controlled manner for an online calibration. The resistance of the at least one transistor, e.g. of a MOSFET, can be selectively changed via an applied gate-source voltage of the transistor, which voltage can be adjusted by an evaluation, control and regulating device used as a further component of the battery sensor, wherein a current which flows between drain and source of the transistor is controlled. This functionality can thereby be used to set a volume resistance and/or measuring resistance, as the resistance of the at least one transistor, exactly to the desired value.

The invention has the result that the accuracy of the battery sensor and an algorithm used for detecting the state of the battery over the service life of said battery can be increased with respect to present-day sensor systems.

A calibration of the battery sensor during production can be partially or even completely eliminated. The costs for power current limiters can likewise be eliminated in production.

If the thermal load on the battery sensor is too high, the volume resistance, as the resistance of the transistor, can be switched to the minimum value thereof in order to, e.g., intermittently reduce the power dissipation until the operating temperature has decreased to a suitable value. This procedure is for the self-protection of said battery sensor.

Flexible operating modes can be implemented for the battery sensor by using the at least one variable resistor embodied as a transistor. In so doing, it is possible to actively control the at least one resistor, as a rule a level of resistance. A higher degree of accuracy can consequently be achieved for small currents to be measured. It is additionally possible in the embodiment to usually automatically readjust the level of resistance of the at least one transistor of the battery sensor in accordance with a level of the current to be measured and therefore to increase a sensitivity of the battery sensor by adapting the resistance. An adaptation of a measurement range of the battery sensor is therefore possible. The resistance of the at least one transistor of the battery sensor is typically set higher as the current to be measured becomes smaller. In addition, a protective function can be implemented by using the battery sensor for the battery, which, e.g., comprises a boundary of a charging current for the battery during charging. An online calibration or a calibration, which is carried out during operation, of the resistance of the at least one transistor of the battery sensor as the measuring resistor, can alternatively or additionally be performed for measuring the at least one operational parameter.

The power electronics of a motor vehicle have now become more powerful and more reliable so that even applications with transistors, which are embodied as power semiconductors in main current paths, become possible. Such a transistor can also be used in the invention and be embodied as a power circuit breaker which limits a short circuit current pulse of a starter and thereby reduces a voltage drop during start-up. The transistor should have a volume resistance value in the micro-ohm range or smaller.

The battery sensor according to the invention is designed for the purpose of carrying out all of the steps of the method presented. Individual steps of said method can also be carried out by individual components of the battery sensor. In addition, functions of the battery sensor or functions of individual components of the battery sensor can be implemented as steps of the method. It is furthermore possible for steps of the method to be implemented as functions of at least one component of the battery sensor or of the complete battery sensor.

Further advantages and embodiments of the invention ensue from the description and the accompanying drawing.

It goes without saying that the previously mentioned features and those still to be explained below cannot only be used in the respective specified combination but also in other combinations or discretely without departing from the scope of the present invention.

### BRIEF DESCRIPTION OF THE DRAWING

FIG. 1 shows a schematic depiction of an embodiment of a battery sensor according to the invention.

### DETAILED DESCRIPTION

The invention is schematically depicted in the drawing using an exemplary embodiment and is described below in detail with reference to the drawing.

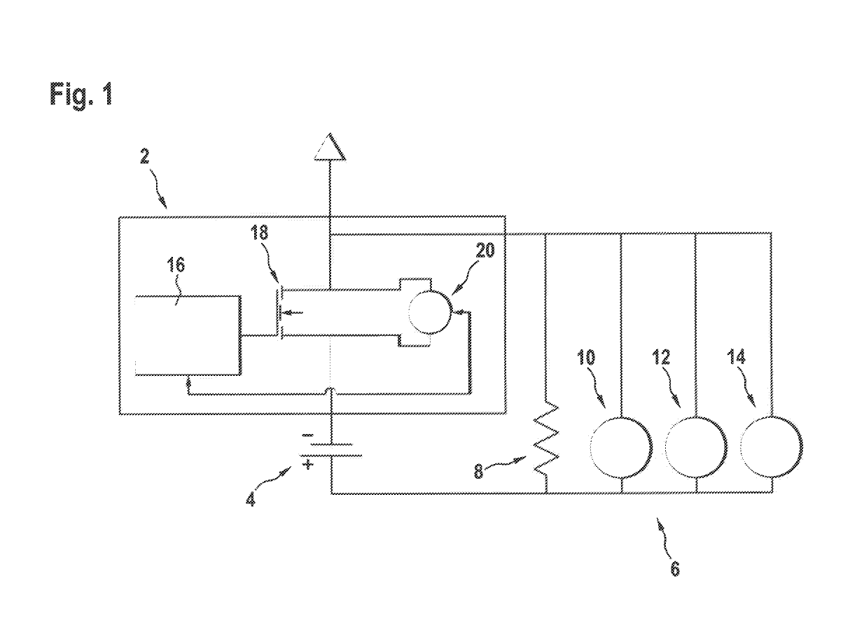

FIG. 1 shows a schematic depiction of an embodiment of the battery sensor 2 according to the invention, which is designed to measure as least one operational parameter of a battery 4. Provision is thereby made for the battery 4 to be configured as a component of an on-board electrical system 6 of a motor vehicle. The on-board electrical system 6 further comprises additional ohmic loads 8, at least one electric motor 10, i.e. one or a plurality of electric motors 10, e.g., for the electrically assisted steering, a generator 12 and a load 14 embodied as a starter.

The battery sensor 2 comprises a logic evaluation, control and regulating device, which in this case is embodied as an electronic circuit, in which an algorithm is implemented for determining at least one operational parameter of the battery 4. The evaluation unit 16 is designed for the purpose of carrying out the algorithm in an embodiment of the method according to the invention. In addition, the battery sensor 2 comprises at least one transistor 18, which in this case is embodied as a power transistor, having controllable resistance as well as a voltage measuring device 20 associated with the transistor 18.

In order to determine a value of the at least one operational parameter of the battery 4 as storage device for electrical energy, a value of the resistance of the at least one transistor 18 is controlled and therefore the measuring range thereof is adapted to the value of the at least one operational parameter. The battery sensor 2 can likewise be used for determining at least one operational parameter of a storage device for electrical energy embodied as a rechargeable battery.

A resistance of the at least one transistor 18 is controlled with the evaluation, control and regulating device 16 and therefore variably adjusted for the measuring range. In order to do this, drain and source of the at least one transistor 18 are connected to the evaluation, control and regulating device 16. The at least one transistor can, e.g., be embodied as a MOSFET.

A current flowing through the battery 4 or a voltage applied to the battery 4 can be measured by the voltage measuring device 20 as the at least one operational parameter. In order to adapt the measuring range, the level of the resistance of the at least one transistor 18 is adapted to the level of the operational parameter of the battery 4 to be measured. Thus, for example, the lower the current to be measured is, which flows through the battery, the higher the resistance is to be set.

In a further embodiment of the inventive battery sensor, a distribution of electrical energy can be controlled and thereby controlled in an open-loop and/or closed-loop system by means of a variable setting of the resistance of the at least one transistor 18 via the evaluation, control and regulating device 16.

A further embodiment of a battery sensor, which is not shown here, can comprise a plurality of transistors 18 having variable resistances. In this case, said transistors 18 are connected to each other in parallel and/or in series. Provision is made in the embodiment for the transistors 18 to be connected in parallel or reversely parallel. The transistors 18 can alternatively or additionally be connected in series or reversely in series. In this case, the drop in voltage across all of the transistors 18 can be measured.

1. A battery sensor for determining at least one operational parameter of a battery, wherein the battery sensor comprises at least one transistor having controllable resistance, which is designed to determine the at least one operational parameter.

2. The battery sensor according to claim 1, which is designed to detect an operational state of the battery.

3. The battery sensor according to claim 1, which is designed to determine the at least one operational parameter of a battery for electrical energy of a motor vehicle.

4. The battery sensor according to claim 1, in which the at least one transistor is designed as a power MOSFET.

5. The battery sensor according to claim 1, which comprises an evaluation, control and regulating device.

6. The battery sensor according to claim 1, which comprises a plurality of transistors connected to each other in parallel.

7. The battery sensor according to claim 1, which comprises a plurality of transistors connected to each other in series.

8. A method for determining at least one operational parameter of a battery , in which the at least one operational parameter is determined with a battery sensor which comprises at least one transistor having a controllable resistance, with which the at least one operational parameter is determined.

9. The method according to claim 8, in which a value of the resistance of the at least one transistor is variably adjusted.

10. The method according to claim 8, in which a current flowing through the battery is measured as the at least one operational parameter, wherein a level of a resistance of the at least one transistor is adapted to a level of the current to be measured.

11. The method according to claim 8, in which a limitation of the charging current for the battery is effected.

12. The m according to claim 8, in which an online calibration is performed.
